(19) United States
(12) Patent Application Publication
(10) Pub. No.: US 2025/0230038 A1
(43) Pub. Date: Jul. 17, 2025

(54) MICRO-ELECTRO-MECHANICAL SYSTEM PACKAGE AND FABRICATION METHOD THEREOF

(71) Applicant: Vanguard International Semiconductor Corporation, Hsinchu (TW)

(72) Inventors: ROHIT PULIKKAL KIZHAKKEYIL, Singapore (SG); Rakesh Chand, Singapore (SG); Poh Liang Yap, Singapore (SG); Ramachandramurthy Pradeep Yelehanka, Singapore (SG)

(73) Assignee: Vanguard International Semiconductor Corporation, Hsinchu (TW)

(21) Appl. No.: 18/415,613

(22) Filed: Jan. 17, 2024

(51) Int. Cl. B81B 7/02; B81C 1/00

(52) U.S. Cl. CPC B81B 7/02; B81C 1/00269; B81B 2201/0235; B81B 2201/0242; B81C 2201/013

(57) ABSTRACT

A MEMS package includes a wafer with an interconnect layer thereon. A first device layer including a first MEMS device with a first thickness is disposed on the wafer and bonded to the interconnect layer. A second device layer including a second MEMS device with a second thickness thinner than the first thickness is disposed on the wafer and bonded to the interconnect layer. A raised electrode is disposed above the interconnect layer and directly below the second MEMS device. A first cap substrate with a first cavity is bonded to the first device layer, where the first MEMS device corresponds to the first cavity. A second cap substrate with a second cavity is bonded to the second device layer, where the second MEMS device corresponds to the second cavity.

### BACKGROUND OF THE INVENTION

### 1. Field of the Invention

The present disclosure relates generally to micro-electro-mechanical system (MEMS) packages, and more particularly to a MEMS package including MEMS devices with different device layer thicknesses and different electrode gaps, and fabrication methods thereof.

### 2. Description of the Prior Art

Micro-electro-mechanical system (MEMS) devices are microscopic devices that integrate mechanical and electrical components to sense physical quantities and/or to interact with the surrounding environment. MEMS devices, such as accelerometers, gyroscopes, pressure sensors and microphones, have found widespread use in many modern electronic products. For example, inertial measurement units (IMU) composed of accelerometers and/or gyroscopes are commonly used in tablet computers, automobiles, or smartphones. For some applications, various MEMS devices need to be integrated into one MEMS package. These MEMS devices may require different device layer thicknesses to meet the requirements in sensitivity and performance. However, in the conventional MEMS packages, for MEMS devices requiring different device layer thicknesses, these MEMS devices are fabricated separately by using different device wafers and then co-packaged. Therefore, the whole fabricating process of the conventional MEMS packages is complicated, and the cost thereof is also increased.

### SUMMARY OF THE INVENTION

In view of this, the present disclosure provides micro-electro-mechanical system (MEMS) packages and fabrication methods thereof to overcome the drawbacks of the conventional MEMS packages. The MEMS package includes different MEMS devices with different device layer thicknesses and different electrode gaps to meet the sensitivities and the performances of various MEMS devices. Moreover, these MEMS devices are fabricated simultaneously by using the same device wafer and packaged simultaneously on the same wafer having an interconnect layer and a raised electrode thereon. Therefore, the whole fabricating process of the MEMS package is simplified and the cost thereof is reduced compared with those of the conventional MEMS packages.

According to one embodiment of the present disclosure, a MEMS package is provided and includes a wafer, a first device layer, a second device layer, a raised electrode, a first cap substrate and a second cap substrate. The wafer has an interconnect layer disposed thereon. The first device layer includes a first MEMS device having a first thickness. The first device layer is disposed on the wafer and bonded to the interconnect layer. The second device layer includes a second MEMS device having a second thickness thinner than the first thickness. The second device layer is laterally spaced apart from the first device layer, disposed on the wafer and bonded to the interconnect layer. The raised electrode is disposed above the interconnect layer and directly below the second MEMS device. The first cap substrate with a first cavity is bonded to the first device layer, where the first MEMS device corresponds to the first cavity. The second cap substrate with a second cavity is laterally spaced apart from the first cap substrate and bonded to the second device layer, where the second MEMS device corresponds to the second cavity.

According to one embodiment of the present disclosure, a method of fabricating a MEMS package is provided and includes the following steps. A cap wafer is provided, and a first cavity and a second cavity are formed in the cap wafer. A device wafer is provided and boned to the cap wafer, where the first cavity and the second cavity are covered by the device wafer. The device wafer is thinned and etched to form a recessed portion corresponding to the second cavity after the device wafer is bonded with the cap wafer and thinned. The device wafer is patterned to form a first MEMS device and a second MEMS device, where the first MEMS device has a first thickness and corresponds to the first cavity, the second MEMS device has a second thickness and corresponds to the second cavity, and the second thickness is thinner than the first thickness. A wafer with an interconnect layer formed thereon is provided. A raised electrode is formed above the interconnect layer. The device wafer is bonded to the interconnect layer on the wafer, where the raised electrode corresponds to the second MEMS device. In addition, a portion of the cap wafer and a portion of the device wafer at a scribe line are removed to form a first cap substrate with the first cavity, a second cap substrate with the second cavity, a first device layer with the first MEMS device, and a second device layer with the second MEMS device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a MEMS package according to one embodiment of the present disclosure.

FIG. 2, FIG. 3, FIG. 4, FIG. 5, FIG. 6, FIG. 7, FIG. 8 and FIG. 9 are schematic cross-sectional views of some stages of a method of fabricating a MEMS package according to one embodiment of the present disclosure.

FIG. 10 shows schematic cross-sectional views of some stages of a method of fabricating a MEMS package according to another embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first”, “second”, and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that may vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to MEMS packages and fabrication methods thereof. The MEMS package includes different MEMS devices with different device layer thicknesses and different electrode gaps. In the MEMS package, a MEMS device requiring a relatively high vacuum has a device layer thickness that is thinner than the device layer thickness of another MEMS device requiring a low vacuum or atmospheric pressure. These MEMS devices are fabricated simultaneously by using the same device wafer and packaged simultaneously on the same wafer having an interconnect layer formed thereon. In addition, a raised electrode is disposed above the interconnect layer and corresponds to the MEMS device with a thinner device layer thickness. An electrode gap for the MEMS device with the thinner device layer thickness is smaller than the electrode gap for the MEMS device with a thicker device layer thickness. The whole fabricating process of the MEMS packages of the present disclosure is simplified. The cost and the time of fabricating the MEMS packages are also reduced. Moreover, the sensitivities and the performances of various MEMS devices are satisfied in the MEMS packages of the present disclosure.

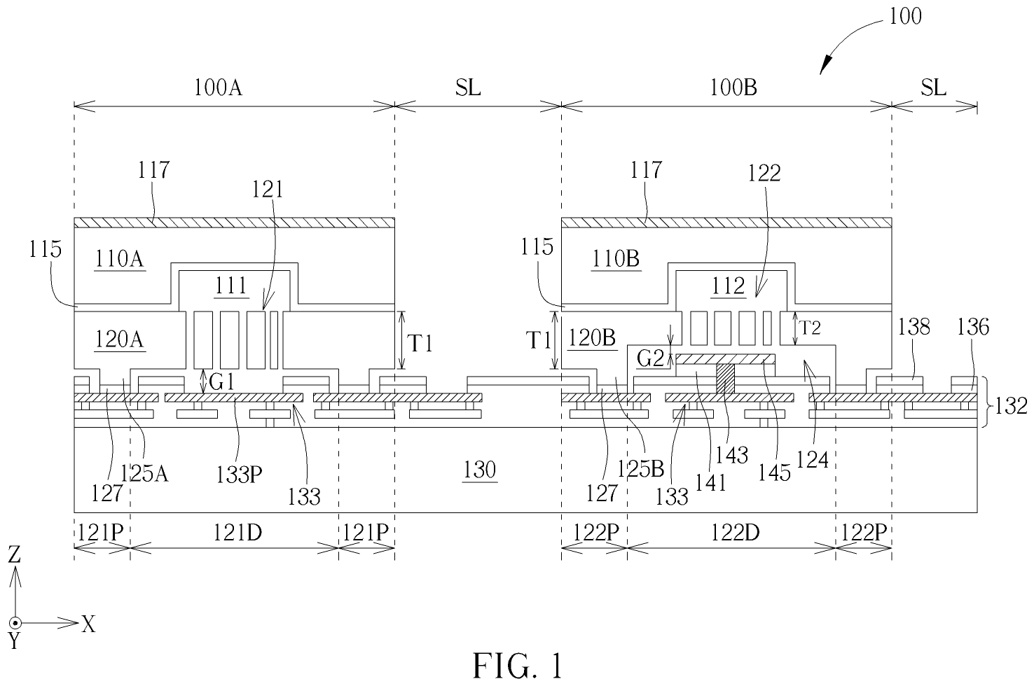

FIG. 1 is a schematic cross-sectional view of a MEMS package 100 according to one embodiment of the present disclosure. The MEMS package 100 includes various MEMS devices with different device layer thicknesses and different electrode gaps to meet the sensitivity and the performance of each MEMS device. These MEMS devices are laterally spaced from each other in an X-axis direction and packaged on the same wafer 130. The wafer 130 may include multiple complementary metal oxide semiconductor (CMOS) transistors or other elements formed therein, and an interconnect layer 132 is disposed on the wafer 130. In one embodiment, the MEMS package 100 includes a first MEMS region 100A and a second MEMS region 100B separated by a scribe line SL. A first MEMS device 121 requiring a low vacuum or atmospheric pressure is located in the first MEMS region 100A. A second MEMS device 122 requiring a relatively high vacuum is located in the second MEMS region 100B. The first MEMS device 121 has a first thickness T1 in a Z-axis direction and is formed in a first device layer 120A. The second MEMS device 122 has a second thickness T2 that is thinner than the first thickness T1 and is formed in a second device layer 120B. The first MEMS device 121 and the second MEMS device 122 have different device layer thicknesses to meet different requirements in the sensitivities and the performances of these MEMS devices. The first device layer 120A and the second device layer 120B are laterally spaced from each other in the X-axis direction, and both are bonded to the interconnect layer 132 on the wafer 130.

In addition, the MEMS package 100 includes a raised electrode 145 disposed above the interconnect layer 132 and directly below the second MEMS device 122. A dielectric layer 141 is disposed between the raised electrode 145 and the interconnect layer 132. A via 143 is disposed to pass through the dielectric layer 141 and a passivation layer 138 and a top dielectric layer 136 of the interconnect layer 132 for electrically connecting the raised electrode 145 to a top metal layer 133 of the interconnect layer 132. In the first MEMS region 100A, a portion 133P of the top metal layer 133 is exposed through an opening of the passivation layer 138 and the top dielectric layer 136 and located directly below the first MEMS device 121.

There is a first gap G1 between the portion 133P of the top metal layer 133 and the bottom surface of the first MEMS device 121 in the Z-axis direction. There is a second gap G2 between the raised electrode 145 and the bottom surface of the second MEMS device 122 in the Z-axis direction. In some embodiments, an electrode (not shown) is formed in the first MEMS device 121, and another electrode (not shown) is formed in the second MEMS device 122. The electrode in the first MEMS device 121 may be electrically coupled to the interconnect layer 132 through the first device layer 120A and stand-off bumps formed at the bottom of the first device layer 120A. The electrode in the second MEMS device 122 may be electrically coupled to the interconnect layer 132 through the second device layer 120B and stand-off bumps formed at the bottom of the second device layer 120B. The entire first device layer 120A is highly conductive and thus the first device layer 120A may be regarded as an upper electrode that interacts with the portion 133P of the top metal layer 133. The entire second device layer 120B is highly conductive and thus the second device layer 120B may be regarded as another upper electrode that interacts with the raised electrode 145.

The portion 133P of the top metal layer 133 is a lower electrode interacting with the upper electrode in the first MEMS device 121, so that the first gap G1 may be referred to as an electrode gap for the first MEMS device 121. The raised electrode 145 is a lower electrode interacting with the upper electrode in the second MEMS device 122, so that the second gap G2 may be referred to as an electrode gap for the second MEMS device 122. In the MEMS package 100, the second gap G2 is smaller than the first gap G1, thereby improving the sensitivity of the second MEMS device 122 having the thinner device layer thickness. The first MEMS device 121 and the second MEMS device 122 have different electrode gaps to meet different requirements in the sensitivity and the performance of these MEMS devices. In some embodiments, the raised electrode 145 may be located directly below a proof mass of the second MEMS device 122 to further improve the sensitivity and the performance of the second MEMS device 122.

Moreover, the second gap G2 is variable and controlled by the thickness of the dielectric layer 141. The second gap G2 is smaller while the dielectric layer 141 is thicker. The thickness of the dielectric layer 141 is dependent on the difference between the first thickness T1 of the first MEMS device 121 and the second thickness T2 of the second MEMS device 122. In some embodiments, the difference between the first thickness T1 and the second thickness T2 is greater than the thickness of the dielectric layer 141. In some embodiments, the raised electrode 145 and the dielectric layer 141 may have the same pattern in a top view, for example, in the XY plane.

In the MEMS package 100, the first MEMS device 121 and the second MEMS device 122 require different vacuum levels. In some embodiments, the first MEMS device 121 may be an accelerometer requiring low vacuum or atmospheric pressure, and the second MEMS device 122 may be a gyroscope requiring high vacuum, but not limited thereto. The MEMS structures of the first MEMS device 121 and the second MEMS device 122 are different from each other. Each of the first MEMS device 121 and the second MEMS device 122 may include features such as standoff bumps, trenches, proof masses, etc., and the layout of these features in the first MEMS device 121 is different from that in the second MEMS device 122. In order to make the figure simple and easy to understand, the MEMS structures of the first MEMS device 121 and the second MEMS device 122 are simplified in FIG. 1.

In addition, as shown in FIG. 1, a first bond seal ring 125A is disposed between the first device layer 120A and the wafer 130, and bonded to the interconnect layer 132 through a bonding material 127. Also, a second bond seal ring 125B is disposed between the second device layer 120B and the wafer 130, and bonded to the interconnect layer 132 through the bonding material 127. In some embodiments, the composition of the bonding material 127 is metal such as germanium (Ge), so that the first bond seal ring 125A and the second bond seal ring 125B are bonded to the top metal layer 133 of the interconnect layer 132 by eutectic bonding. The first bond seal ring 125A and the first device layer 120A are connected with each other to be an integral structure. Also, the second bond seal ring 125B and the second device layer 120B are connected with each other to be an integral structure.

Still referring to FIG. 1, the MEMS package 100 includes the first cap substrate 110A with a first cavity 111, and the second cap substrate 110B with a second cavity 112. The first cap substrate 110A and the second cap substrate 110B are formed from the same cap wafer and have the same composition such as silicon. The first cap substrate 110A and the second cap substrate 110B are laterally spaced apart from each other in the X-axis direction. A bonding layer 115 is disposed between the first device layer 120A and the first cap substrate 110A. Another bonding layer 115 is disposed between the second device layer 120B and the second cap substrate 110B. The composition of the bonding layer 115 may be silicon oxide. The first cap substrate 110A is bonded to the first device layer 120A through the bonding layer 115 by fusion bonding. The second cap substrate 110B is also bonded to the second device layer 120B through the bonding layer 115 by fusion bonding. In some embodiments, the bonding layer 115 may be further extended into the first cavity 111 and the second cavity 112 to be conformally disposed on the sidewalls and the bottom surfaces of the first cavity 111 and the second cavity 112.

As shown in FIG. 1, the first cavity 111 is located directly above and corresponds to the first MEMS device 121. The second cavity 112 is located directly above and corresponds to the second MEMS device 122. In some embodiments, the first MEMS device 111 is an accelerometer, and the second MEMS device 122 is a gyroscope. The first cavity 111 has a first pressure, and the second cavity 112 has a second pressure lower than the first pressure. In addition, the conductive layer 117 is disposed on the backside surfaces of the first cap substrate 110A and the second cap substrate 110B. The composition of the conductive layer 117 is, for example, aluminum (Al). The conductive layer 117 may be formed without patterning or a patterned conductive layer, which is dependent on the electrical requirements of the first MEMS device 121 and the second MEMS device 122. The first MEMS device 121 and the second MEMS device 122 are electrically coupled to different portions of the conductive layer 117 separately. The conductive layer 117 may be further electrically coupled to the interconnect layer 132.

Moreover, referring to FIG. 1, the first device layer 120A includes a first device portion 121D and a first peripheral portion 121P that abuts and surrounds the first device portion 121D. Also, the second device layer 120B includes a second device portion 122D and a second peripheral portion 122P that abuts and surrounds the second device portion 122D. In some embodiments, the first device portion 121D, the first peripheral portion 121P and the second peripheral portion 122P all have the first thickness T1. The second device portion 122D has the second thickness T2 that is thinner than the first thickness T1. In one embodiment, the boundary between the first peripheral portion 121P and the first device portion 121D may be vertically aligned with the inner sidewalls of the first bond seal ring 125A. Also, the boundary between the second peripheral portion 122P and the second device portion 122D may be vertically aligned with the inner sidewalls of the second bond seal ring 125B.

In addition, the second device layer 120B has a recessed portion 124 facing towards the interconnect layer 132, and the raised electrode 145 is located in the recessed portion 124. In one embodiment, the sidewalls of the recessed portion 124 are vertically aligned with the inner sidewalls of the second bond seal ring 125B. In other embodiments, the sidewalls of the recessed portion 124 may retracted inward towards the second cavity 112 and not vertically aligned with the inner sidewalls of the second bond seal ring 125B.

Furthermore, in other embodiments, the MEMS package 100 may further include other MEMS devices requiring vacuum levels different from those of the first MEMS device 121 and the second MEMS device 122. For example, a third MEMS region (not shown) including a third MEMS device is disposed laterally spaced from the first MEMS region 100A and the second MEMS region 100B by the scribe line SL. A third device layer (not shown) including the third MEMS device is also packaged on the same wafer 130. The third MEMS device may have a device layer thickness different from the first thickness T1 and the second thickness T2. Moreover, the third MEMS device may have an electrode gap different from the first gap G1 and the second gap G2. Another raised electrode (not shown) may be disposed above the interconnect layer 132 and directly below the third MEMS device. Alternatively, another portion of the top metal layer 133 may be exposed through an opening of interconnect layer 132 and located directly below the third MEMS device. The MEMS structure of the third MEMS device may be different from those of the first MEMS device 121 and the second MEMS device 122. The MEMS packages of the present disclosure are suitable for 1-axis, 2-axis, 3-axis and 6-axis inertial measurement unit (IMU) and other MEMS devices requiring different device layer thicknesses and different electrode gaps.

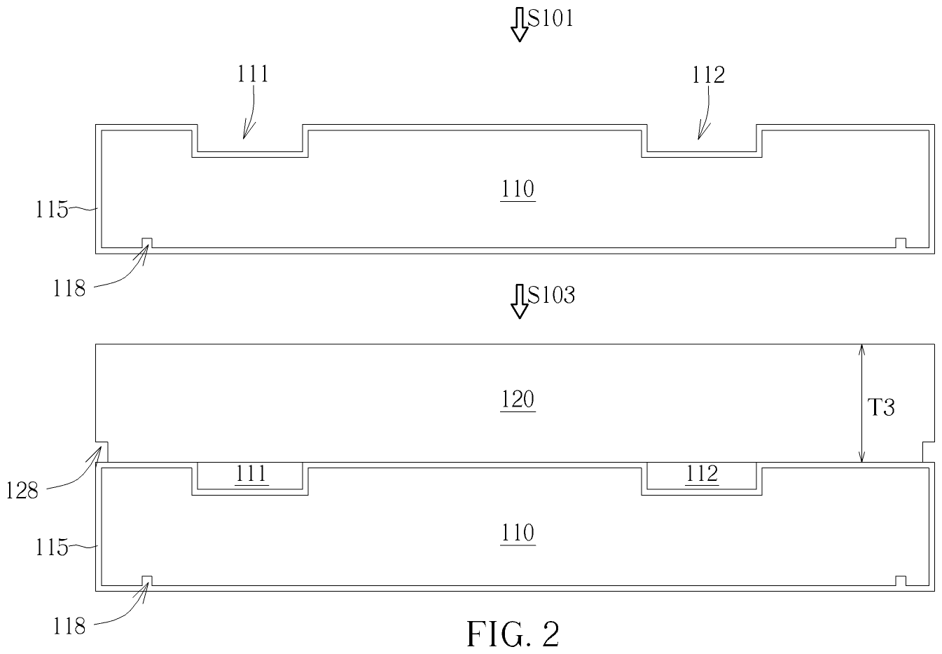

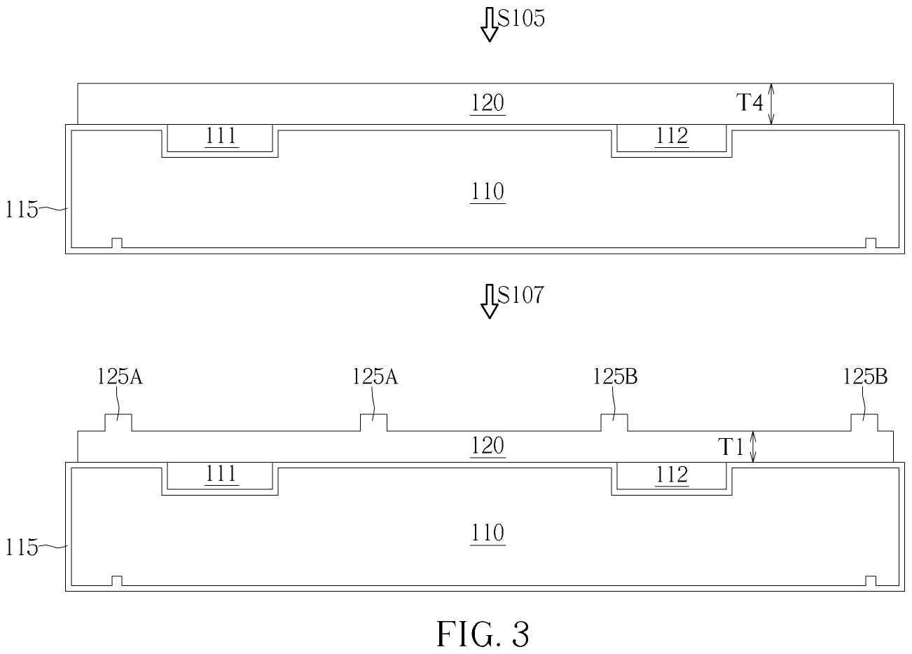

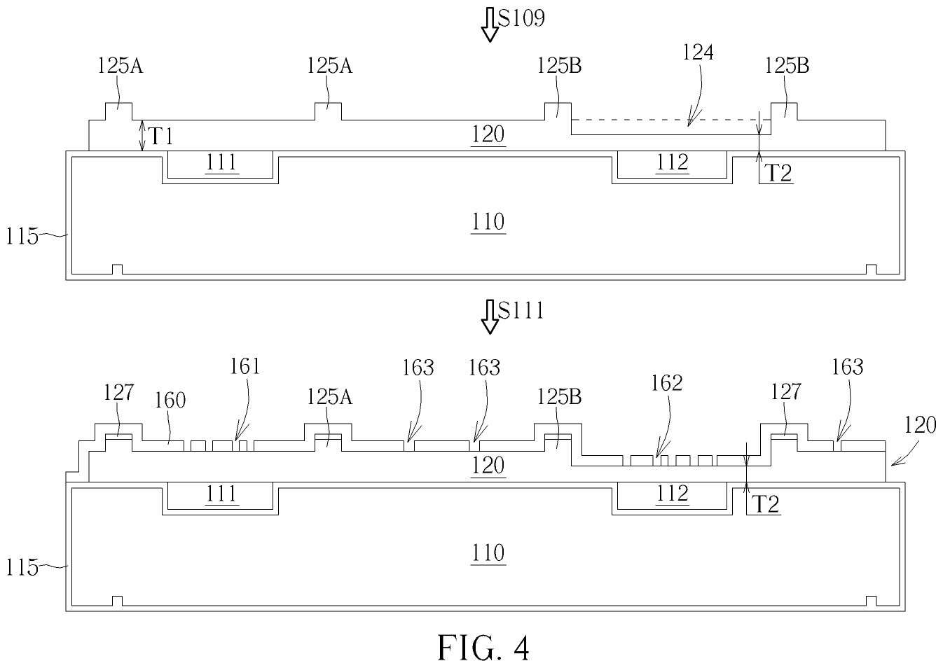

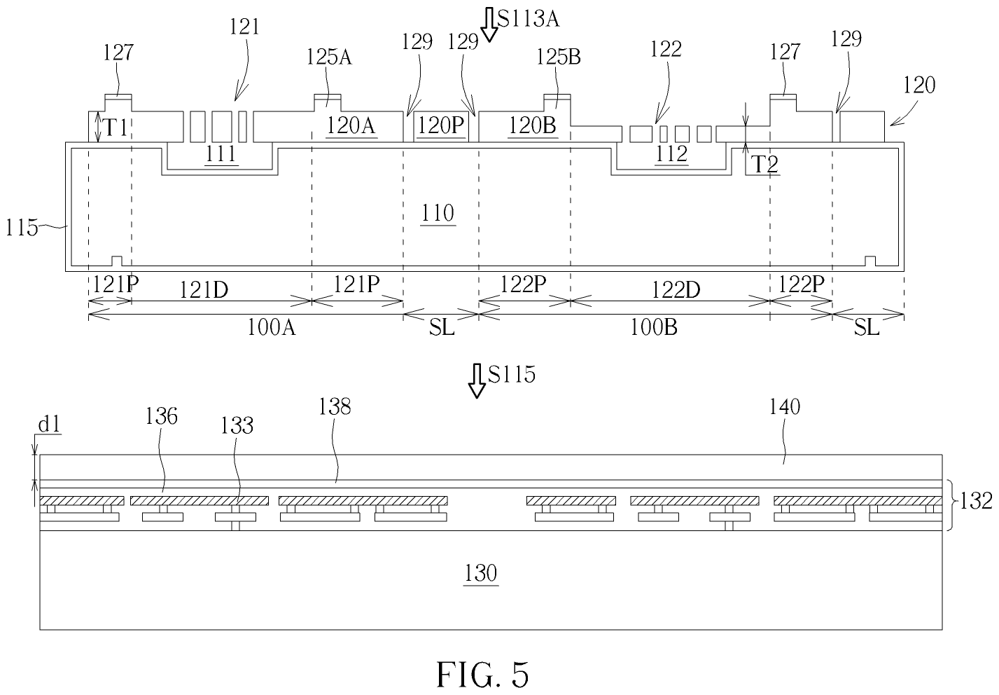

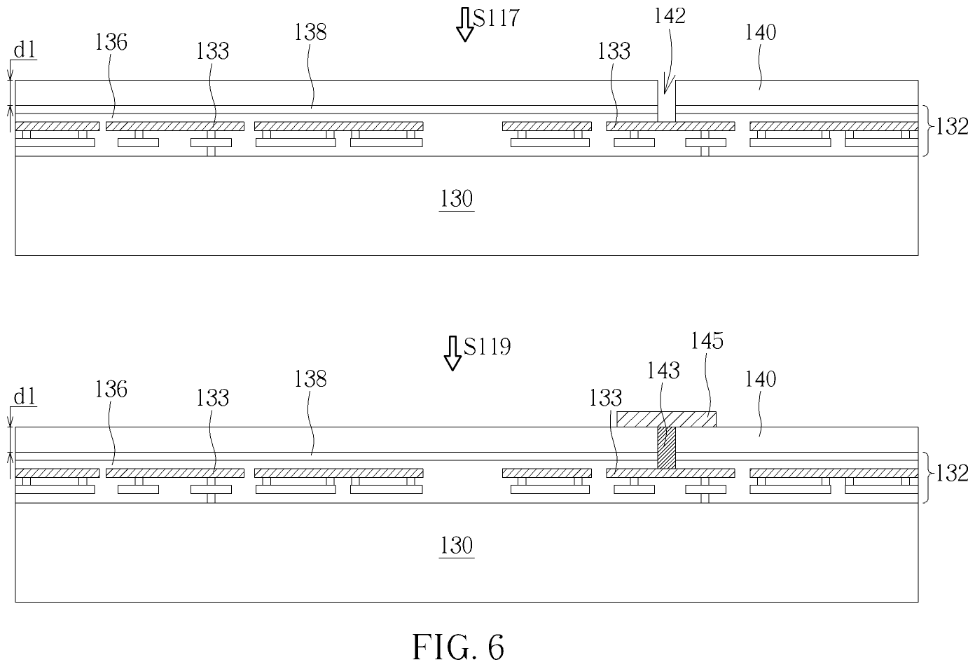

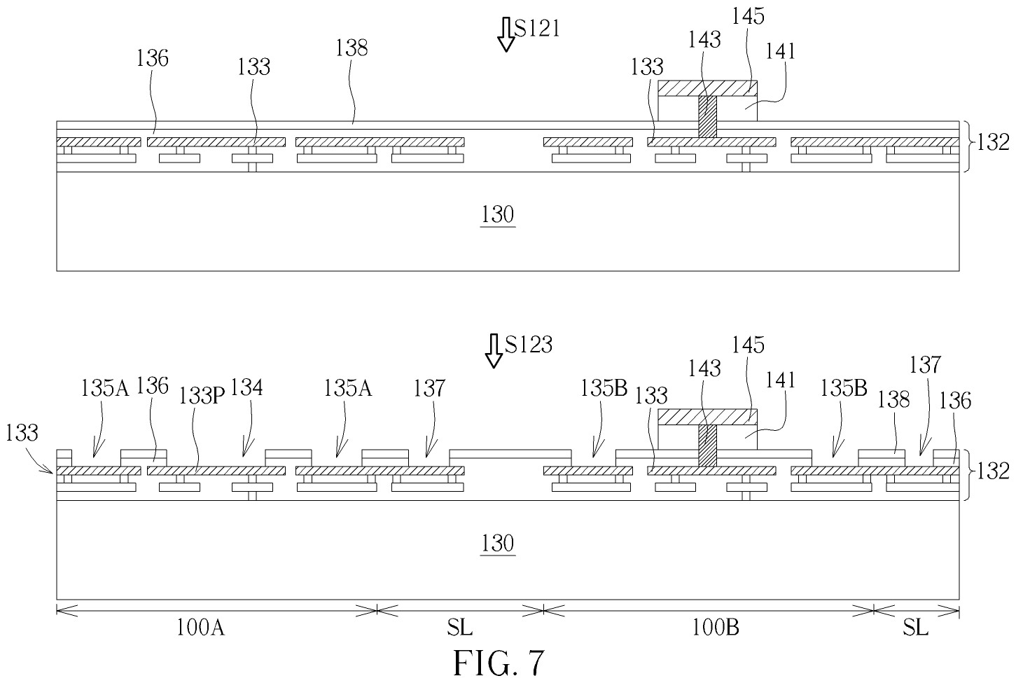

FIG. 2, FIG. 3, FIG. 4, FIG. 5, FIG. 6, FIG. 7, FIG. 8 and FIG. 9 are schematic cross-sectional views of some stages of a method of fabricating a MEMS package 100 according to one embodiment of the present disclosure. Referring to FIG. 2, in step S101, firstly, a cap wafer 110 such as a silicon wafer is provided. Then, a first cavity 111 and a second cavity 112 are formed on the front surface of the cap wafer 110 by an etching process. Moreover, alignment marks 118 are formed on the back surface of the cap wafer 110. Then, a bonding layer 115 is conformally formed on the front surface, the sidewalls and the back surface of the cap wafer 110 and in the first cavity 111 and the second cavity 112 to wrap around the cap wafer 110. The bonding layer 115 is also formed on the sidewalls and the bottom surfaces of the first cavity 111 and the second cavity 112. The composition of the bonding layer 115 is, for example, silicon oxide. The bonding layer 115 may be formed by a thermal oxidation process or a deposition process.

Next, still referring to FIG. 2, in step S103, a device wafer 120 such as a silicon wafer is provided. The edges 128 of the device wafer 120 are trimmed, and then the device wafer 120 is bonded with the cap wafer 110 through the bonding layer 115 by fusion bonding using an annealing process. After bonding with the cap wafer 110, the device wafer 120 covers the first cavity 111 and the second cavity 112. In step S103, the device wafer 120 has a thickness T3.

Then, referring to FIG. 3, in step S105, the device wafer 120 is thinned from the thickness T3 in step S103 to a thickness T4 by a back grinding (BG) process and a chemical-mechanical planarization (CMP) process. Next, still referring to FIG. 3, in step S107, the device wafer 120 is etched to form stand-off bumps, a first bond seal ring 125A and a second bond seal ring 125B. After the step S107, the device wafer 120 has a first thickness T1 that is thinner than the thickness T4 in step S105.

Thereafter, referring to FIG. 4, in step S109, the device wafer 120 is etched to form a recessed portion 124 corresponding to the second cavity 112. In one embodiment, the sidewalls of the recessed portion 124 are vertically aligned with the inner sidewalls of the second bond seal ring 125B as shown in FIG. 4. In other embodiments, the sidewalls of the recessed portion 124 may be retracted inward towards the second cavity 112 and not vertically aligned with the inner sidewalls of the second bond seal ring 125B. After the device wafer 120 is etched to form the recessed portion 124, a portion of the device wafer 120 directly below the recessed portion 124 has a second thickness T2 that is thinner than the first thickness T1. The other portion of the device wafer 120 has the first thickness T1. The second thickness T2 of the device wafer 120 is variable and controlled by the etching process in step S109 to form the recessed portion 124.

Next, still referring to FIG. 4, in step S111, firstly, a bonding material 127 such as Ge is formed on the first bond seal ring 125A and the second bond seal ring 125B by deposition and patterning processes. Then, a patterned mask layer 160 is conformally formed on the device wafer 120 and in the recessed portion 124 by spray coating and patterning processes. In one embodiment, the patterned mask layer 160 is a photoresist layer patterned by a photolithography process. The patterned mask layer 160 has multiple openings and/or slits 161, 162 and 163. Referring to FIG. 1 and FIG. 4, the openings and/or slits 161 are located in the first MEMS region 100A for forming the first MEMS device 121. The openings and/or slits 162 are located in the second MEMS region 100B for forming the second MEMS device 122. The slits 163 are located at the scribe line SL for forming pre-cut lines.

Then, referring to FIG. 5, in step S113A, the device wafer 120 is patterned by an etching process through the openings and/or slits 161, 162 and 163 of the patterned mask layer 160 to simultaneously form the first MEMS device 121, the second MEMS device 122 and pre-cut lines 129. The first MEMS device 121 has the first thickness T1 and corresponds to the first cavity 111. The second MEMS device 122 has the second thickness T2 that is thinner than the first thickness T1 and corresponds to the second cavity 112. The pre-cut lines 129 are located at the scribe line SL. The device wafer 120 is divided into a first device layer 120A and a second device layer 120B by the pre-cut lines 129. The first device layer 120A incudes a first device portion 121D and a first peripheral portion 121P both having the first thickness T1. The second device layer 120B includes a second device portion 122D having the second thickness T2 and a second peripheral portion 122P having the first thickness T1. The second device portion 122D is located between the recessed portion 124 and the second cavity 112. The first MEMS device 121 is formed by patterning the first device portion 121D having the first thickness T1, and the second MEMS device 122 is formed by patterning the second device portion 122D having the second thickness T2. The first bond seal ring 125A is connected with the first peripheral portion 121P of the first device layer 120A to be an integral structure. Also, the second bond seal ring 125B is connected with the second peripheral portion 122P of the second device layer 120B to be an integral structure.

Still referring to FIG. 5, in step S115, firstly, a wafer 130 with an interconnect layer 132 formed thereon is provided. The wafer 130 may be a silicon wafer including multiple CMOS transistors or other elements formed therein, and may be referred to as a CMOS wafer. The interconnect layer 132 includes multiple metal layers, multiple inter-metal dielectric (IMD) layers, and multiple vias in the IMD layers to connect two metal layers. The metal layers include a top metal layer 133. The IMD layers include a top dielectric layer 136 formed on the top metal layer 133. The interconnect layer 132 further includes a passivation layer 138 deposited on the top dielectric layer 136. The composition of the metal layers is for example aluminum (Al). The composition of the IMD layers is for example silicon oxide. The composition of the passivation layer 138 is for example silicon oxide, silicon nitride, silicon oxynitride or a combination thereof. In addition, a dielectric material layer 140, for example a silicon oxide layer, is deposited on the passivation layer 138. The dielectric material layer 140 has a thickness d1 that is adjusted based on the difference between the first thickness T1 and the second thickness T2. Moreover, the thickness d1 of the dielectric material layer 140 may be smaller than the difference between the first thickness T1 and the second thickness T2.

Next, referring to FIG. 6, in step S117, an opening 142 is formed in the dielectric material layer 140, the passivation layer 138 and the top dielectric layer 136 by an etching process with a patterned mask. A portion of the top metal layer 133 is exposed through the opening 142. Then, still referring to FIG. 6, in step S119, the opening 142 is filled up with a conductive material to form a via 143. Thereafter, a conductive material layer such as an aluminum (Al) layer is deposited on the dielectric material layer 140 and in direct contact with the via 143. Then, the conductive material layer is patterned by photolithography and etching processes to form a raised electrode 145 in direct contact with the via 143 and located above the interconnect layer 132.

Then, referring to FIG. 7, in step S121, the dielectric material layer 140 is etched by using the raised electrode 145 as a mask to form a dielectric layer 141 that is located between the raised electrode 145 and the interconnect layer 132. The dielectric layer 141 may have the same pattern as the raised electrode 145 in a top view. The via 143 passes through the dielectric layer 141 and electrically connects the raised electrode 145 to the top metal layer 133 of the interconnect layer 132.

Next, still referring to FIG. 7, in step S123, multiple openings 134, 135A, 135B and 137 are formed in the passivation layer 138 and the top dielectric layer 136 by photolithography and etching processes. A portion 133P of the top metal layer 133 in the first MEMS region 100A is exposed by the opening 134. The portion 133P is used as an electrode for the first MEMS device 121. A first bind ring area of the top metal layer 133 in the first MEMS region 100A is exposed by the opening 135A. A second bind ring area of the top metal layer 133 in the second MEMS region 100B is exposed by the opening 135B. A bond pad area of the top metal layer 133 at the scribe line SL is exposed by the opening 137.

Afterwards, referring to FIG. 8, in step S125, the structure including the device wafer 120 bonded with the cap wafer 110 in step S113A of FIG. 5 is turned upside down and bonded with the wafer 130 in step S123 of FIG. 7. The device wafer 120 is bonded to the interconnect layer 132 on the wafer 130 at a first pressure, so that firstly, both the first cavity 111 and the second cavity 112 have the first pressure. The first bond seal ring 125A and the second bond seal ring 125B of the device wafer 120 are bonded to the top metal layer 133 of the interconnect layer 132 through the bonding material 127 by eutectic bonding. After the device wafer 120 is bonded with the wafer 130, the raised electrode 145 is located directly below and corresponds to the second MEMS device 122. In one embodiment, the raised electrode 145 is located directly below a proof mass of the second MEMS device 122. In some embodiments, several raised electrodes 145 are formed above the interconnect layer 132 and respectively correspond to a proof mass and other features of the second MEMS device 122.

In step S125, the cap wafer 110 has a thickness T5, and the wafer 130 has a thickness T7. Then, referring to FIG. 9, in step S127, the cap wafer 110 is thinned by back grinding or dry etching to have a thickness T6 that is thinner than the thickness T5 in step S125 of FIG. 8. The bonding layer 115 on the backside of the cap wafer 110 is also removed. Moreover, the wafer 130 is also thinned by back grinding or dry etching to have a thickness T8 that is thinner than the thickness T7 in step S125 of FIG. 8.

Next, still referring to FIG. 9, in step S129, in one embodiment, a conductive layer 117 is formed by depositing a metal layer such as an aluminum layer on the backside of the thinned cap wafer 110, where the conductive layer 117 is formed without patterning. In another embodiment, the aforementioned metal layer is then patterned by photolithography and etching processes to form a conductive layer 117 with patterning. The conductive layer 117 is used for grounding the cap wafer 110 and thus the conductive layer 117 may be formed with or without patterning.

Afterwards, a portion of the cap wafer 110 and a portion 120P of the device wafer 120 at the scribe line SL between the pre-cut lines 129 are removed by a sawing process to complete the MEMS package 100 of FIG. 1. In the MEMS package 100, the bond pads on the interconnect layer 132 at the scribe line SL are exposed. In some embodiments, the bond pad of the first MEMS device 121 and the bond pad of the second MEMS device 122 are disposed on one side of the interconnect layer 132 and located at the same scribe line SL. Thus, one scribe line SL is enough to expose the bond pads for both the first MEMS device 121 and the second MEMS device 122. In addition, the first cap substrate 110A with the first cavity 111 and the second cap substrate 110B with the second cavity 112 are formed and laterally spaced from each other. Also, the first device layer 120A with the first MEMS device 121 and the second device layer 120B with the second MEMS device 122 are laterally spaced from each other. Moreover, the pressure in the first cavity 111 is maintained at the first pressure. In some embodiments, the pressure in the second cavity 112 is reduced from the first pressure to a second pressure through a vent hole in the second cap substrate 110B by vacuum pumping or other methods to reduce the pressure in the second cavity 112. Therefore, the first cavity 111 has the first pressure, and the second cavity 112 has the second pressure lower than the first pressure.

In some embodiments, the first MEMS device 121 with the first thickness T1 is, for example, an accelerometer, and the second MEMS device 122 with the second thickness T2 thinner than the first thickness T1 is, for example, a gyroscope, but not limited thereto. Moreover, the electrode gap for the second MEMS device 122, i.e., the second gap G2 between the raised electrode 145 and the bottom surface of the second MEMS device 122, is smaller than the electrode gap for the first MEMS device 121, i.e., the first gap G1 between the portion 133P of the top metal layer 133 and the bottom surface of the first MEMS device 121. The first MEMS device 121 and the second MEMS device 122 are fabricated by using the same device wafer 120 and packaged on the same wafer 130 to complete the MEMS package 100.

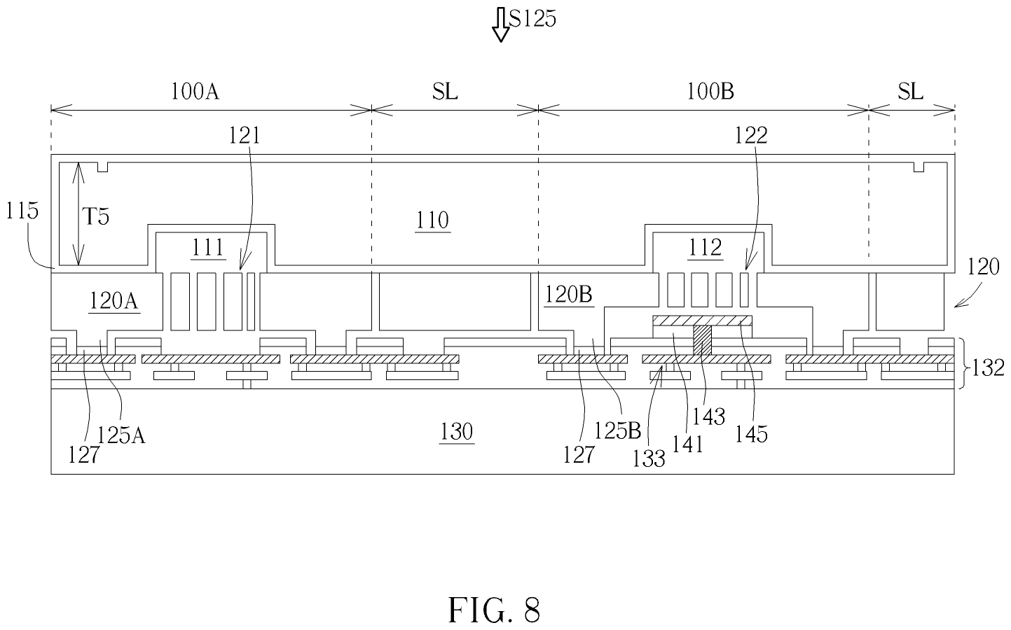

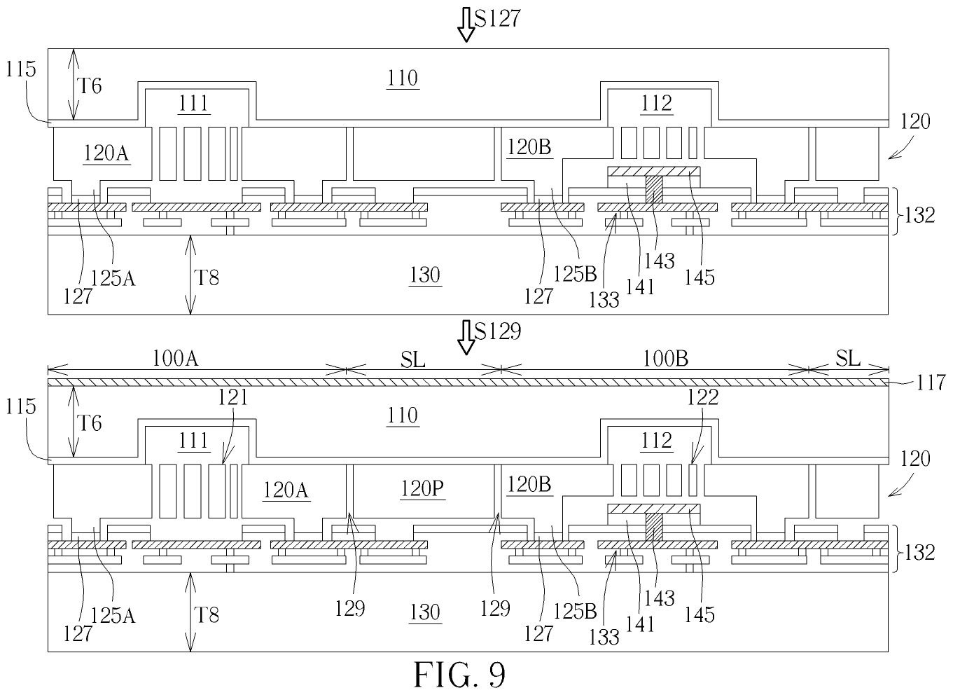

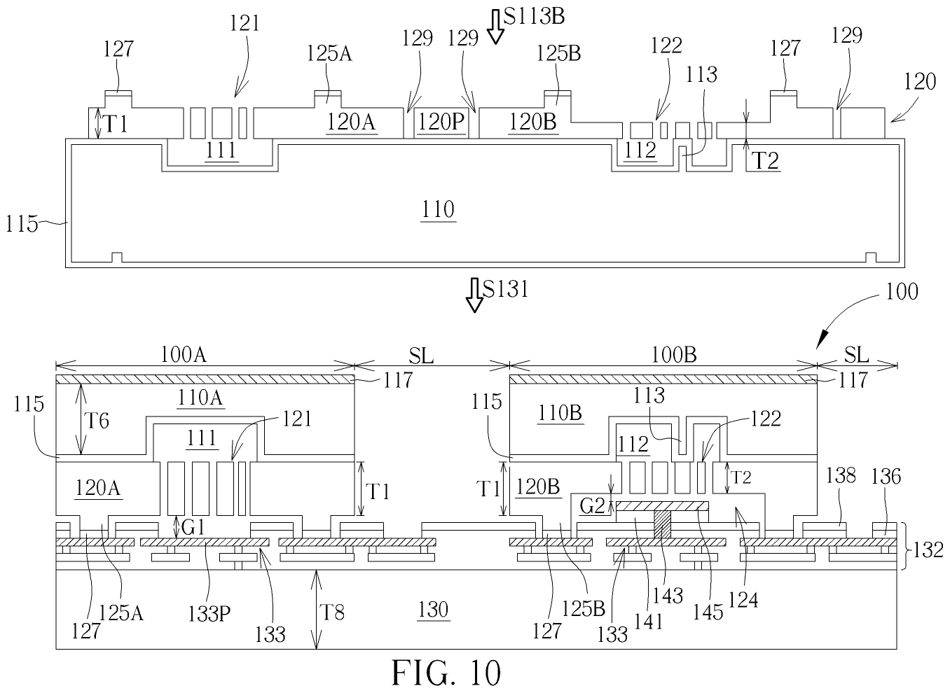

FIG. 10 shows schematic cross-sectional views of some stages of a method of fabricating a MEMS package 100 according to another embodiment of the present disclosure. Referring to FIG. 2 and FIG. 10, in one embodiment, the first cavity 112, the second cavity 112 and a stopper 113 are simultaneously formed by etching the cap wafer 110. The stopper 113 is formed in the second cavity 112 and connected with the bottom surface of the second cavity 112. The bonding layer 115 is also conformally deposited on the stopper 113. After the aforementioned steps S103, S105, S107, S109 and S111 are performed on the device wafer 120, referring to FIG. 10, in step S113B, the device wafer 120 is patterned by an etching process to simultaneously form the first MEMS device 121, the second MEMS device 122 and the pre-cut lines 129. The stopper 113 is bonded to the second device layer 120B through the bonding layer 115, so that the stopper 113 supports the second device portion 122D of the second device layer 120B during patterning the device wafer 120. In one embodiment, the stopper 113 is located at an anchor end of the second MEMS device 122 for attaching the second MEMS device 122 to the second cap substrate 110B. In another embodiment, the bonding layer 115 between the stopper 113 and the second device layer 120B may be removed after the second MEMS device 122 is formed, so that the stopper 113 is released from the second MEMS device 122 based on the requirement. The details of the other features in step S113B of FIG. 10 may refer to the aforementioned description in step S113A of FIG. 5, and are not repeated herein.

After the aforementioned steps S115, S117, S119, S121, S123, S125, S127 and S129 are performed, referring to FIG. 10, in step S131, a portion of the cap wafer 110 and a portion 120P of the device wafer 120 at the scribe line SL between the pre-cut lines 129 are removed by a sawing process to complete the MEMS package 100 of FIG. 10. In one embodiment, as shown in FIG. 10, the stopper 113 is bonded with the second device portion 122D of the second device layer 120B and corresponds to an anchor end of the second MEMS device 122. In another embodiment, the stopper 113 may be released from the second MEMS device 122. The details of the other features of the MEMS package 100 in FIG. 10 may refer to the aforementioned description of the MEMS package 100 in FIG. 1, and are not repeated herein. The methods of fabricating the MEMS packages 100 as described in the steps of FIG. 2 to FIG. 10 may be used to fabricate other MEMS packages including more MEMS devices different from the first MEMS device 121 and the second MEMS device 122.

According to the embodiments of the present disclosure, the MEMS package includes different MEMS devices with different device layer thicknesses and different electrode gaps to meet the sensitivities and the performances of various MEMS devices. These MEMS devices are fabricated simultaneously by using the same device wafer and packaged simultaneously on the same wafer having the interconnect layer and the raised electrode formed thereon, thereby simplifying the whole fabricating process and reducing the cost of the MEMS packages.

Moreover, in the MEMS packages, the raised electrode is disposed above the interconnect layer and corresponds to the MEMS device with a thinner device layer thickness, thereby reducing the electrode gap and improving the sensitivity of the MEMS device. Furthermore, the dielectric layer is disposed between the raised electrode and the interconnect layer. Therefore, the electrode gap between the raised electrode and the bottom of the MEMS device is variable and controlled by the thickness of the dielectric layer to ensure the sensitivity of the MEMS device. Also, the fabrication of the raised electrode is compatible with the fabricating process of the CMOS wafer.

Furthermore, the device layer thicknesses of different MEMS devices are precisely controlled by thinning and etching the same device wafer without additional device wafer. Therefore, the sensitivities and the performances of the different MEMS devices are satisfied, and the cost and the time of fabricating the MEMS packages are reduced. In addition, the MEMS packages of the present disclosure do not require individual wire bonding, thereby reducing the parasitic effect. The MEMS packages of the present disclosure are suitable for 1-axis, 2-axis, 3-axis and 6-axis inertial measurement unit (IMU) and other MEMS devices requiring different device layer thicknesses and different electrode gaps.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-electro-mechanical system (MEMS) package, comprising:
a wafer with an interconnect layer;
a first device layer comprising a first MEMS device having a first thickness, disposed on the wafer and bonded to the interconnect layer;
a second device layer comprising a second MEMS device having a second thickness thinner than the first thickness, laterally spaced apart from the first device layer, disposed on the wafer and bonded to the interconnect layer;
a raised electrode, disposed above the interconnect layer and directly below the second MEMS device;
a first cap substrate with a first cavity, bonded to the first device layer, wherein the first MEMS device corresponds to the first cavity; and
a second cap substrate with a second cavity, laterally spaced apart from the first cap substrate, and bonded to the second device layer, wherein the second MEMS device corresponds to the second cavity.

2. The MEMS package of claim 1, further comprising:
a dielectric layer, disposed between the raised electrode and the interconnect layer; and
a via, passing through the dielectric layer and electrically connecting the raised electrode to the interconnect layer.

3. The MEMS package of claim 2, wherein a difference between the first thickness and the second thickness is greater than a thickness of the dielectric layer.

4. The MEMS package of claim 2, wherein the raised electrode and the dielectric layer have the same pattern in a top view.

5. The MEMS package of claim 2, wherein the raised electrode is located directly below a proof mass of the second MEMS device.

6. The MEMS package of claim 1, wherein the interconnect layer comprises a top metal layer, a portion of the top metal layer is exposed through an opening and located directly below the first MEMS device, a first gap is between the portion of the top metal layer and the first MEMS device, a second gap is between the raised electrode and the second MEMS device, and the second gap is smaller than the first gap.

7. The MEMS package of claim 1, wherein the first MEMS device comprises an accelerometer, the second MEMS device comprises a gyroscope, the first cavity has a first pressure, and the second cavity has a second pressure lower than the first pressure.

8. The MEMS package of claim 1, wherein the second device layer comprises a recessed portion facing towards the interconnect layer, and the raised electrode is located in the recessed portion.

9. The MEMS package of claim 8, further comprising:
a first bond seal ring, disposed between the first device layer and the wafer, and bonded to the interconnect layer; and
a second bond seal ring, disposed between the second device layer and the wafer, and bonded to the interconnect layer,
wherein a sidewall of the recessed portion is vertically aligned with an inner sidewall of the second bond seal ring.

10. The MEMS package of claim 1, wherein the first device layer comprises a first device portion and a first peripheral portion abutting the first device portion, the second device layer comprises a second device portion and a second peripheral portion abutting the second device portion, the first device portion, the first peripheral portion and the second peripheral portion have the first thickness, and the second device portion has the second thickness.

11. A method of fabricating a micro-electro-mechanical system (MEMS) package, comprising:
providing a cap wafer;
forming a first cavity and a second cavity in the cap wafer;
providing a device wafer;
bonding the device wafer to the cap wafer, wherein the first cavity and the second cavity are covered by the device wafer;
thinning the device wafer;
etching the device wafer to form a recessed portion corresponding to the second cavity after the device wafer is bonded with the cap wafer and thinned;
patterning the device wafer to form a first MEMS device and a second MEMS device, wherein the first MEMS device has a first thickness and corresponds to the first cavity, the second MEMS device has a second thickness and corresponds to the second cavity, and the second thickness is thinner than the first thickness;
providing a wafer with an interconnect layer formed thereon;
forming a raised electrode above the interconnect layer;
bonding the device wafer to the interconnect layer on the wafer, wherein the raised electrode corresponds to the second MEMS device; and
removing a portion of the cap wafer and a portion of the device wafer at a scribe line to form a first cap substrate with the first cavity, a second cap substrate with the second cavity, a first device layer with the first MEMS device, and a second device layer with the second MEMS device.

12. The method of claim 11, further comprising:
forming a dielectric layer between the raised electrode and the interconnect layer; and
forming a via passing through the dielectric layer and electrically connecting the raised electrode to the interconnect layer.

13. The method of claim 12, wherein forming the raised electrode, forming the dielectric layer and forming the via comprise:
depositing a dielectric material layer over the interconnect layer;
etching the dielectric material layer and a portion of interconnect layer to form an opening;
filling the opening to form the via;
depositing a conductive material layer on the dielectric material layer and in direct contact with the via;
patterning the conductive material layer to form the raised electrode; and
etching the dielectric material layer by using the raised electrode as a mask to form the dielectric layer.

14. The method of claim 11, wherein a thickness of the dielectric layer is adjusted based on and smaller than a difference between the first thickness and the second thickness.

15. The method of claim 11, further comprising etching the device wafer to form a first bond seal ring and a second bond seal ring after the device wafer is thinned and before etching the device wafer to form the recessed portion.

16. The method of claim 15, wherein a sidewall of the recessed portion is vertically aligned with an inner sidewall of the second bond seal ring.

17. The method of claim 11, wherein patterning the device wafer comprises:
conformally forming a patterned mask layer on the device wafer and in the recessed portion by a spray coating process; and
etching the device wafer through openings of the patterned mask layer to simultaneously form the first MEMS device and the second MEMS device.

18. The method of claim 11, wherein the first MEMS device is formed by patterning a first device portion of the device wafer having the first thickness, the second MEMS device is formed by patterning a second device portion of the device wafer having the second thickness, and the second device portion is located between the recessed portion and the second cavity.

19. The method of claim 18, wherein forming the second cavity in the cap wafer further comprises forming a stopper in the second cavity and connected with a bottom surface of the second cavity, and the stopper is bonded with the second device portion of the device wafer.

20. The method of claim 11, wherein the first MEMS device comprises an accelerometer, the second MEMS device comprises a gyroscope, the first cavity has a first pressure, and the second cavity has a second pressure lower than the first pressure.
